(19) United States
(12) Patent Application Publication
(10) Pub. No.: US 2009/0076751 A1
(43) Pub. Date: Mar. 19, 2009

(54) SYSTEMS AND METHODS FOR MEASURING SIGNAL WAVEFORMS

(75) Inventors: SHEN-CHUN LI, Tu-Cheng (TW); SHOU-KUO HSU, Tu-Cheng (TW); HSIEN-CHUAN LIANG, Tu-Cheng (TW); HUNG CHAO, Tu-Cheng (TW); DUEN-YI HO, Tu-Cheng (TW); YING-TSO LAI, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/172,257

(22) Filed: Jul. 13, 2008

(30) Foreign Application Priority Data
Sep. 17, 2007 (CN) 200710201723.8

(51) Int. Cl. G01R 13/00

(52) U.S. Cl. 702/66

(57) ABSTRACT

A system for measuring a signal waveform is provided. The system comprises a parameter receiving module, a waveform receiving module, a waveform filter, and a data storing module. The parameter receiving module is configured for receiving one or more filtration conditions. The waveform receiving module is configured for receiving the signal waveform. The waveform filter is configured for filtering the signal waveform to obtain a desired waveform. The data storing module is configured for storing the desired waveform into a storage device.

### FIELD OF THE INVENTION

Embodiments of the present disclosure relate to systems and methods for testing electronic signals, and more particularly to systems and methods for measuring signal waveforms.

### DESCRIPTION OF RELATED ART

Digital storage oscilloscopes (DSOs) and other measurement devices may analyze an electronic signal in order to measure various characteristics of the electronic signal. These measurement devices may comprise a trigger system to trigger in response to various events of the electronic signal, such as an edge, a level, a glitch, a slew rate, and a runt, for example. Accordingly, the triggering may result in capturing a desired waveform from an electronic device.

Furthermore, a measurement device usually provides a plurality of channels (e.g., four channels), each of which may be used as a trigger source to simultaneously observe analog characteristics of several electronic signals. However, it is difficult to capture desired waveforms for more complicated observations, such as simultaneously testing several electronic signals in high-speed circuits. For example, while testing a high-speed memory chip or a central processing module (CPU), electronic signals with a specified timing are desired to be observed. In this case, a user often has to manually control the measurement device by repeatedly pressing a capture button until desired waveforms are finally captured. This method is often inefficient and labor intensive.

What is needed, therefore, is systems and methods for measuring signal waveforms allowing for a more efficient and less labor intensive way to capture and analyze signal waveforms.

### SUMMARY

A system for measuring a signal waveform is provided. The system comprises a parameter receiving module, a waveform receiving module, a waveform filter, and a data storing module. The parameter receiving module is configured for receiving one or more filtration conditions. The waveform receiving module is configured for receiving the signal waveform. The waveform filter is configured for filtering the signal waveform to obtain a desired waveform, wherein the filtering comprises determining logic matrices for the signal waveform according to the one or more filtration conditions. The data storing module is configured for storing the desired waveform into a storage device.

Other objects, advantages and novel features will become more apparent from the following detailed description of certain embodiments of the present disclosure when taken in conjunction with the accompanying drawings, in which:

### BRIEF DESCRIPTION OF THE DRAWINGS

FIG. 1 is a block diagram of one embodiment of a system for measuring waveforms of electronic signals;

FIG. 2 is a block diagram of one embodiment of a measurement unit comprising function modules;

FIG. 3 is a main flowchart of one embodiment of a method for measuring signal waveforms;

FIG. 4 is a flowchart illustrating one embodiment of determining logic matrices for signal waveforms according to filtration conditions;

FIG. 5 illustrates one embodiment of feature points of a signal waveform over one period;

FIG. 6 illustrates one embodiment of several voltage measurements of an electronic signal; and

FIG. 7 illustrates one embodiment of several time measurements of an electronic signal.

### DETAILED DESCRIPTION OF CERTAIN INVENTIVE EMBODIMENTS

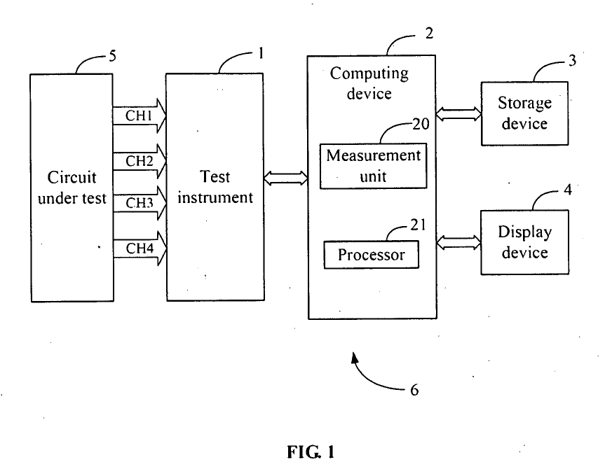

FIG. 1 is a block diagram of one embodiment of a system 6 for measuring waveforms of electronic signals (i.e. “signal waveforms”). The system 6 includes a test instrument 1, a computing device 2, a storage device 3 and a display device 4. The computing device 2 connects to the storage device 3 and the display device 4. The computing device 2 further connects to the test instrument 1 via an input/output (I/O) interface, such as a serial port, a GPIB port, or a LAN port, for example.

The test instrument 1 is configured for capturing signal waveforms from a circuit under test (CUT) 5. The signal waveforms may be in a format of *.cvs, *.xls or any other suitable files, for example. In one embodiment, the test instrument 1 may be a digital storage oscilloscope (DSO) or any other test device that can capture signal waveforms. In one embodiment, the test instrument 1 provides four channels (such as CH1, CH2, CH3, and CH4) connected to the CUT 5 for testing electronic signals from the CUT 5.

The CUT 5 may comprise a motherboard, a CPU, or a high-speed memory chip, such as a double-data rate (DDR) memory. Accordingly, the CUT 5 may comprise a clock signal. A channel (e.g., CH1) of the test instrument 1 may be connected to the clock signal. Other channels (e.g., CH2, CH3, and CH4) of the test instrument 1 may be connected to three other electronic signals of the CUT 5 to be analyzed. The test instrument 1 may simultaneously capture a set of signal waveforms including a CH1 waveform (i.e., a clock signal waveform), a CH2 waveform, a CH3 waveform, and a CH4 waveform. It may be understood that a signal waveform is a graph of voltage plotted against time, with voltage represented by a Y-axis, and time represented by an X-axis of a coordinate axis system. It may be further understood that each of a set of signal waveforms may be divided into a plurality of waveform segments on the X-axis of the coordinate axis system, where each of the signal waveform segments represents a clock period interval.

Filtration conditions may be used to define criteria that desired waveforms are required to fit. For example, conditions about timing (hereinafter, “timing conditions”), conditions about single channel signal integrity (SI) parameter (hereinafter, “single channel SI parameter conditions”), and condition about inter-channel SI parameter (hereinafter, “inter-channel SI parameter conditions”) may compose the filtration conditions and will be further explained herein. Depending on the embodiment, the filtration conditions may include any combination of conditions as mentioned above.

The computing device 2 includes a measurement unit 20. It may be understood that the computing device 2 may comprise one or more processors, such a processor 21 to execute the measurement unit 20. The measurement unit 20 is configured for controlling the test instrument 1 to capture signal waveforms from the CUT 5 via the respective channels and for receiving the signal waveforms from the test instrument 1. The measurement unit 20 may filter the signal waveforms to obtain one or more desired waveforms according to filtration conditions and store the desired waveforms into the storage device 3. Furthermore, the measurement unit 20 may be configured for analyzing the desired waveforms in accordance with a user's preference, and output a result to the display device 4. The desired waveforms have at least one waveform segment that meets at least one of the filtration conditions as described above. The user's preference may include a time-domain analysis, a frequency-domain analysis, and an abnormal signal analysis, for example. The user's preference, in one embodiment, may correspond to a user controlling the computing device 2 via a test file, where the test file comprises instructions for the computing device 2.

The storage device 3 communicates with the computing device 2, and is configured for storing the desired waveforms transmitted from the computing device 2.

The display device 4 is configured for displaying a result of an analysis of the desired waveforms from the measurement unit 20. The display device 4 may comprise one or more displays arranged in various positions to display the result of the desired waveform analysis.

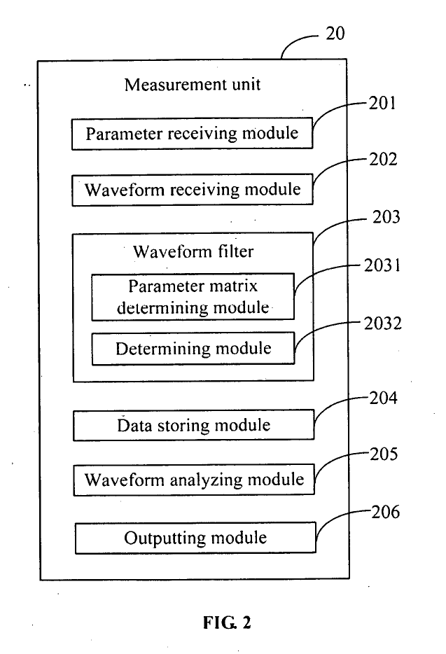

FIG. 2 is a block diagram of one embodiment of the measurement unit 20 comprising function modules. In one embodiment, the measurement unit 20 comprises a parameter receiving module 201, a waveform receiving module 202, a waveform filter 203, a data storing module 204, a waveforms analyzing module 205, and an outputting module 206.

The parameter receiving module 201 is configured for receiving a predetermined number and one or more filtration conditions defined by a user. Depending on the embodiment, the predetermined number may define a number of sets of desired waveforms that meet the one or more filtration conditions, or define a number of waveform segments that meet the one or more filtration conditions. Each time the test instrument 1 obtains a set of signal waveforms from the CUT 5, the set of signal waveforms may contain more than one waveform segment that meet the one or more filtration conditions.

The waveform receiving module 202 is configured for generating and sending instructions to the test instrument 1 so as to control the test instrument 1 to respond to the instructions. The instructions include establishing connections, initializing, and causing triggers, for example. The waveform receiving module 202 is further configured for receiving the signal waveforms from the test instrument 1.

The waveform filter 203 is configured for filtering the signal waveforms to obtain desired waveforms according to the one or more filtration conditions. The waveform filter 203 includes a parameter matrix determining module 2031 and a determining module 2032. The parameter matrix determining module 2031 is configured for determining related matrices for the signal waveforms, such as a voltage matrix, a feature point matrix, a SI parameter matrix, a timing logic matrix, a single channel SI logic matrix, and an inter-channel SI logic matrix, for example. The determining module 2032 is configured for determining if the signal waveforms are a set of desired waveforms, and for determining if a count of desired waveforms is less than the predetermined number. It may be understood that the count of desired waveforms may be the count of sets of desired waveforms.

The data storing module 204 is configured for storing the desired waveforms into the storage device 3.

The waveforms analyzing module 205 is configured for analyzing the desired waveforms according to a user's preference. As mentioned above, the user's preference may include a time-domain analysis, a frequency-domain analysis, and an abnormal signal analysis, for example.

The outputting module 206 is configured for outputting a result of an analysis of the desired waveforms to the display device 4.

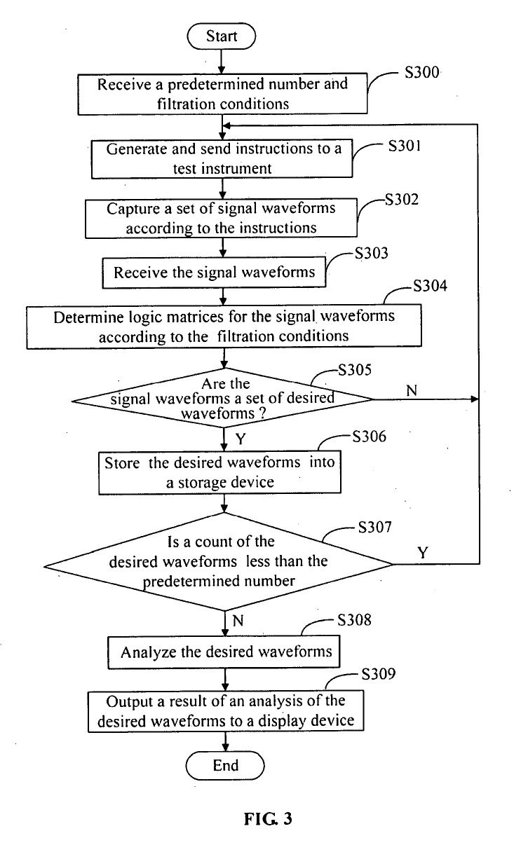

FIG. 3 is a main flowchart of one embodiment of a method for measuring signal waveforms. The method of FIG. 3 may be used in order to analyze and measure a set of desired waveforms from the CUT 5. Depending on the embodiment, ordering of the blocks may be changed, blocks may be added, and others removed.

In block S300, the parameter receiving module 201 receives a predetermined number and one or more filtration conditions determined by a user. As mentioned above, the predetermined number may define a number of sets of desired waveforms that meet the one or more filtration conditions, or define a number of waveform segments that meet the one or more filtration conditions. Each time the test instrument 1 obtains a set of signal waveforms from the CUT 5, the set of signal waveforms may contain one or more waveform segment that meet the filtration conditions.

In block S301, the waveform receiving module 202 generates and sends instructions to the test instrument 1 so as to control the test instrument 1 to respond to the instructions. As mentioned above, the test instrument 1 may trigger on events such as an edge, a level, a glitch, and a runt. For example, the test instrument 1 may trigger on a rise of a clock signal. To obtain sufficient data, in one embodiment, the test instrument 1 captures as much data as it can on each trigger.

In block S302, the test instrument 1 captures a set of signal waveforms according to the instructions. In one particular example, the test instrument 1 captures four signal waveforms from the CUT 5, which comprises a clock signal waveform.

In block S303, the waveform receiving module 204 receives the set of signal waveforms (i.e. the four signal waveforms) from the test instrument 1.

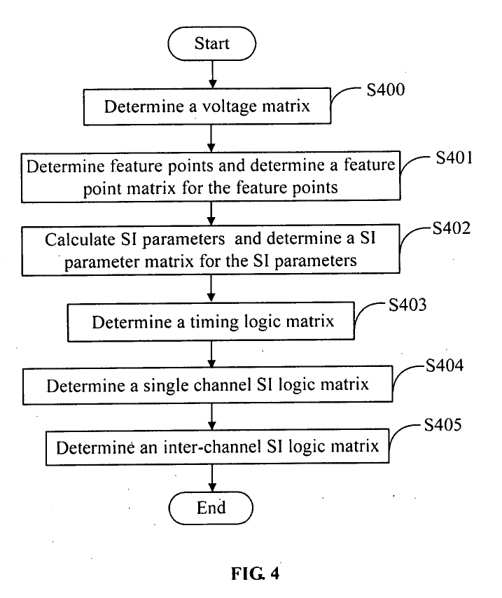

In block S304, the parameter matrix determining module 2031 determines logic matrices for the set of signal waveforms according to the filtration conditions. As mentioned above, the logic matrices may include a timing logic matrix, a single channel SI logic matrix, and an inter-channel SI logic matrix. Before determining the logic matrices, the parameter matrix determining module 2031 may determine voltage matrices and the SI parameter matrices for the signal waveforms. Further details of determining logic matrices are described in FIG. 4.

In block S305, the determining module 2032 determines if the set of signal waveforms are a set of desired waveforms. The determining module may check the logic matrices determined in block S304 as explained in greater detail in FIG. 4. If the signal waveforms are not a set of desired waveforms, then the flow may move to block S301.

If the signal waveforms are a set of desired waveforms, in block S306, then the data storing module 204 stores the desired waveforms into the storage device 3. It may be understood that the data storing module 204 may only store representative data of the desired waveforms into the storage device 3, such as the voltage matrices and the SI parameter matrices, for example.

In block S307, the determining module 2032 determines if a count of the desired waveforms is less than the predetermined number. If the count of the desired waveforms is less than the predetermined number, then the flow may move to block S301.

Otherwise, if the count of the desired waveforms is equal to the predetermined number, in block S308, then the waveforms analyzing module 205 analyzes the desired waveforms according to the user's preference.

In block S309, the outputting module 206 outputs a result of an analysis of the desired waveforms to the display device 4.

FIG. 4 is a flowchart illustrating one embodiment of determining logic matrices for the signal waveforms according to the filtration conditions. The method of FIG. 4 may be used to analyze and measure electronic signals, wherein the electronic signals correspond to a clock period. The method of FIG. 4 illustrates detailed steps as described with respect to block S304 in FIG. 3. In one embodiment, to facilitate illustration, it is assumed that the filtration conditions include timing conditions, single channel SI parameter conditions, and inter-channel SI parameter conditions. Depending on the embodiment, ordering of the blocks may be changed, blocks may be added, and others removed.

In block S400, the parameter matrix determining module 2031 may determine a voltage matrix for the signal waveforms. The voltage matrix may define a column number of the voltage matrix equal to a number of sampling points of each signal waveform captured by the test instrument 1. It may be understood that a matrix may have one or more rows and one or more columns defining the matrix. For example, a 3×5 matrix has a column number 5 and a row number 3.

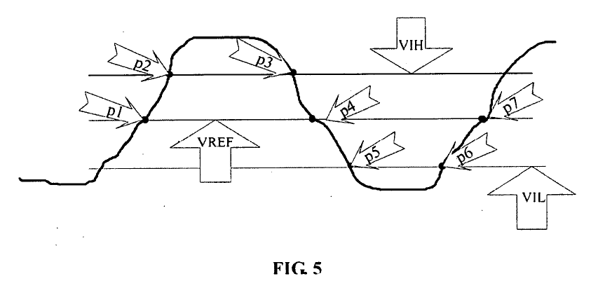

In block S401, the parameter matrix determining module 2031 determines feature points for the signal waveforms, and correspondingly determines a feature point matrix. Further details of determining the feature point matrix are described below with respect to FIG. 5.

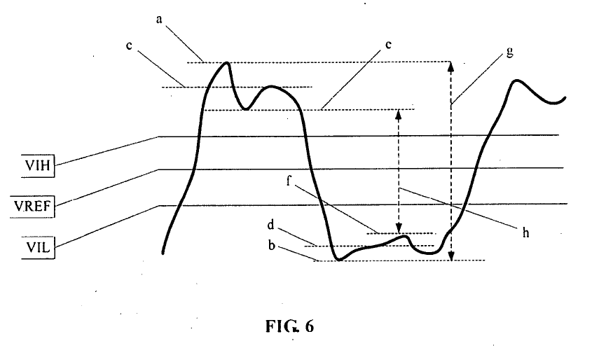

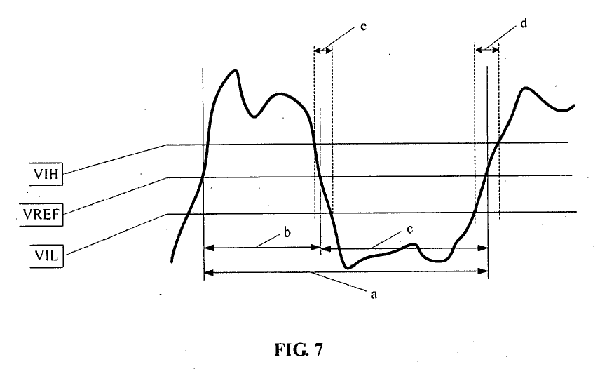

In block S402, the parameter matrix determining module 2031 calculates SI parameters for the signal waveforms, and correspondingly determines a SI parameter matrix. Further details of determining the SI parameter matrix are described below with respect to FIG. 6 and FIG. 7.

In block S403, the parameter matrix determining module 2031 determines a timing logic matrix by determining if each of the waveform segments satisfies the timing conditions according to the filtration conditions. The timing logic matrix may define a column number of the timing logic matrix equal to a period number of of the clock signal waveform. For example, if the clock signal waveform comprises 100 clock periods, then the column number of the timing logic matrix is 100, that is, the timing logic matrix has 100 columns. In one embodiment, results derived from the determining module 2032 may be represented as numbers, character strings, or Boolean quantities. Correspondingly, the timing logic matrix may be in a form of numbers, character strings, or Boolean quantities.

In block S404, the parameter matrix determining module 2031 determines a single channel SI logic matrix by determining if each of the waveform segments satisfies the single channel SI parameter conditions according to the filtration conditions. The single channel SI matrix may define a column number of the single channel SI matrix equal to a period number of the clock signal waveform. It may be understood that results derived from the determining module 2032 may be represented as numbers, character strings, or Boolean quantities. Correspondingly, the single channel SI logic matrix may be in a form of numbers, character strings, or Boolean quantities. The single channel SI parameter conditions may include, a positive pulse width, a negative pulse width, a rise time, and a fall time, for example. In one particular example, a single channel SI parameter condition for the channel A is a positive pulse width between 1.775 ns and 1.975 ns for a waveform segment, assuming a positive pulse width matrix of channel A is [0, 1.780, 1.525, 1.850, 0]. However, in another particular example, if “0” denotes true, and “1” denotes false, then a single channel SI logic matrix for channel A may be [0, 1, 0, 1, 0]. However, it may be understood that the single channel SI logic matrix, as well as other determined matrices may be much more complicated than the above mentioned matrices.

In block S405, the parameter matrix determining module 2031 determines an inter-channel SI logic matrix by determining if each of the waveform segments satisfies inter-channel SI parameter conditions according to the filtration conditions. The inter-channel SI logic matrix may define a column number of the s inter-channel SI logic matrix equal to a certain period of the clock signal waveform. It may be understood that results derived from the determining module 2032 may be represented as numbers, character strings, or Boolean quantities. Correspondingly, the inter-channel SI logic matrix may be in a form of numbers, character strings, or Boolean quantities. The inter-channel SI parameter conditions include, a positive pulse width difference, a negative pulse width difference, a rise time difference, a fall time difference, for example. For example, one inter-channel SI parameter condition is that a positive pulse width of channel A has to be greater than a positive pulse width of channel B. Assuming that a positive pulse width matrix of channel A is [0, 1.780, 1.525, 1.850, 0], a positive pulse width matrix of channel B is [0, 1.770, 1.545, 1.830, 0], and “0” denotes true, and “1” denotes false, then an inter-channel SI logic matrix may be [0, 1, 0, 1, 0], in one particular example.

FIG. 5 illustrates one embodiment of feature points of a signal waveform over one period. The signal waveform may correspond to an input high voltage (VIH), a reference voltage (VREF), and an input low voltage (VIL). Accordingly, seven feature points (“p1” through “p7” shown in FIG. 5) may be derived from the signal waveform. It may be understood that the terms VIH, VREF, and VREF are well-known terms in the field of circuit design. For an electronic signal over n periods, a matrix P1, a matrix P2, . . . , a matrix P7 may be defined for the electronic signal, wherein P1=[p1₁,p1₂, . . . ,p1ₙ], . . . , P7=[p7₁,p7₂, . . . ,p7ₙ]. A feature point matrix may be determined for each investigated electronic signal, and the feature point matrix may define a column of the feature point matrix to be equal to the period number of the clock signal. Using the feature point matrix, various parameters of the electronic signal, such as a period, a positive pulse width, a negative pulse width, a rise time, and a fall time may be calculated.

FIG. 6 illustrates one embodiment of several voltage measurements of an electronic signal, and FIG. 7 illustrates one embodiment of several time measurements of an electronic signal. SI parameters for characterizing an electronic signal may include various voltage measurements as shown in FIG. 6. Referring to FIG. 6, wherein “a” denotes an overshoot, “b” denotes an undershoot, “c” denotes a DC voltage high, “d” denotes a DC voltage low, “e” denotes a ringdown (i.e., a lowest edge of vibration on a stable range of a positive half-wave), “f” denotes a ringup (i.e., a lowest edge of vibration on a stable range of a negative half-wave), “g” denotes an amplitude, “h” denotes a ringback (i.e., a difference between a ringdown and a ringup). The SI parameters may also include time measurements as shown in FIG. 7. Referring to FIG. 7, wherein “a” denotes a period, “b” denotes a positive pulse width, “c” denotes a negative pulse width, “d” denotes a rise time, “e” denotes a fall time. According to the feature points p1-p7, various SI parameters of a single period of the electronic signal may be calculated. For example, the period of the electronic signal may be defined as a value of p1 subtracted from a value of p7, the positive pulse width of the electronic signal may be defined as a value of p1 subtracted from a value of p4, and where a negative pulse width of the electronic signal may be defined as a value of p4 subtracted from a value of p7. For each investigated electronic signal, the S1 parameters of each period of the electronic signal (i.e., the investigated signal period) may be calculated, and a SI parameter matrix with an equal column number as a period number of the clock signal may be determined.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A system for measuring a signal waveform, the system comprising:
a parameter receiving module configured for receiving one or more filtration conditions;
a waveform receiving module configured for receiving the signal waveform;
a waveform filter configured for filtering the signal waveform to obtain a desired waveform, wherein the filtering comprises determining logic matrices for the signal waveform according to the one or more filtration conditions; and
a data storing module configured for storing the desired waveform into a storage device.

2. The system as claimed in claim 1, further comprising a waveform analyzing module configured for analyzing the desired waveform according to a user defined test file.

3. The system as claimed in claim 2, further comprising a outputting module for outputting a result of an analysis of the desired waveform.

4. The system as claimed in claim 1, wherein the one or more filtration conditions comprise a timing condition, a single channel SI parameter condition, and an inter-channel SI parameter condition.

5. The system as claimed in claim 4, wherein the waveform filter comprises:
a parameter matrix determining module configured for determining at least one of a timing logic matrix, a single channel SI logic matrix, and an inter-channel SI logic matrix, wherein the parameter matrix determining module is configured for determining if each of waveform segments in the signal waveform satisfies the timing condition, the single channel SI parameter condition, and the inter-channel SI parameter condition; and
a determining module configured for determining if the signal waveform is a desired waveform according to the timing logic matrix, the single channel SI logic matrix, and the inter-channel SI logic matrix.

6. A computer-based method for measuring a signal waveform of a circuit using a test instrument, the method comprising:
(a) receiving filtration conditions for the signal waveform;
(b) generating and sending instructions to the test instrument;
(c) capturing the signal waveform from the circuit via the test instrument;
(d) receiving the signal waveform from the test instrument;
(e) determining logic matrices for the signal waveform according to the filtration conditions;
(f) determining if the signal waveform is a desired waveform according to the logic matrices; and
(g) storing the desired waveform into a storage device upon the condition that the signal waveform is a desired waveform.

7. The method as claimed in claim 6, wherein the filtration conditions define at least one of a timing condition, a single channel SI parameter condition, and an inter-channel SI parameter condition.

8. The method as claimed in claim 6, further comprising:
analyzing the desired waveform and outputting a result of an analysis of the desired waveform to a display device.

9. The method as claimed in claim 8, wherein the analyzing comprises a time-domain analysis, a frequency-domain analysis, and an abnormal signal analysis.

10. The method as claimed in claim 6, wherein block (e) comprises:
determining a voltage matrix for the signal waveform;
determining feature points for the signal waveform, and determining a feature point matrix for the feature points for the signal waveform;
calculating signal integrity parameters for the signal waveform, and determining a SI parameter matrix for the signal integrity parameters for the signal waveform;
determining a timing logic matrix for the signal waveform;
determining a single channel SI logic matrix for the signal waveform; and
determining an inter-channel SI logic matrix for the signal waveform.

11. The method as claimed in claim 6, wherein the test instrument is a digital storage oscilloscope.

12. A computer-readable medium having stored thereon instructions for measuring an signal waveform, when executed by a computer, causing the computer to:
receive filtration conditions for the signal waveform;
generate and send instructions to a test instrument to capture the signal waveform;
receive the signal waveform from the test instrument;
determine logic matrices for the signal waveform according to the filtration conditions;
determine if the signal waveform is a desired waveform according to the logic matrices; and
store the desired waveform into a storage device upon the condition that the signal waveform is a desired waveform.
